(19) United States
(12) Patent Application Publication
(10) Pub. No.: US 2023/0309415 A1
(43) Pub. Date: Sep. 28, 2023

(54) MAGNETO RESISTIVE ELEMENT

(71) Applicant: TDK Corporation, Tokyo (JP)

(72) Inventors: Katsuyuki NAKADA, Tokyo (JP); Tomoyuki SASAKI, Tokyo (JP)

(73) Assignee: TDK Corporation, Tokyo (JP)

(21) Appl. No.: 17/702,092

(22) Filed: Mar. 23, 2022

(51) Int. Cl. H01L 43/06; H01L 43/10; H01L 43/04

(52) U.S. Cl. CPC H01L 43/04; H01L 43/06; H01L 43/10

(57) ABSTRACT

A magneto resistive element includes a laminate including a first ferromagnetic layer, a second ferromagnetic layer, and a non-magnetic layer and an insulating layer configured to cover at least a part of a side surface of the laminate and including an insulator. The first ferromagnetic layer has a first non-nitride region and a first nitride region that is closer to the insulating layer than the first non-nitride region and contains nitrogen.

### BACKGROUND OF THE INVENTION

### Field of the Invention

The present invention relates to a magneto resistive element.

### Description of Related Art

A magneto resistive element is an element whose resistance value in a lamination direction changes due to the magneto resistive effect. A magneto resistive element includes two ferromagnetic layers and a non-magnetic layer sandwiched between the two ferromagnetic layers. A magneto resistive element in which a conductor is used for a non-magnetic layer is called a giant magneto resistive (GMR) element, and a magneto resistive element in which an insulating layer (a tunnel barrier layer or a barrier layer) is used for a non-magnetic layer is called a tunnel magneto resistive (TMR) element. The magneto resistive element can be applied to various applications such as a magnetic sensor, a high-frequency component, a magnetic head, and a non-volatile random-access memory (MRAM) (for example, Patent Documents 1 and 2). For example, Patent Document 3 describes a method of controlling a direction of magnetization using spin transfer torque (STT) generated by flowing a current through a magneto resistive element in the lamination direction. This method is called a spin injection magnetization reversal method.

### Patent Documents

[Patent Document 1] Japanese Pat. Publication No. 5586028
[Patent Document 2] Japanese Pat. Publication No. 5988019
[Patent Document 3] Japanese Unexamined Pat. Application, First Publication No. 2015-156501

### SUMMARY OF THE INVENTION

It is desirable to reduce energy required for magnetization reversal so that the magnetization reversal is facilitated.

The present invention has been made in view of the above circumstances and an objective of the present invention is to provide a magneto resistive element capable of reversing magnetization with less energy.

According to a first aspect, a magneto resistive element includes a laminate and an insulating layer. The laminate includes a first ferromagnetic layer, a second ferromagnetic layer, and a non-magnetic layer. The insulating layer covers at least a part of a side surface of the laminate. The first ferromagnetic layer has a first non-nitride region and a first nitride region. The first nitride region is closer to the insulating layer than the first non-nitride region. The first nitride region contains nitrogen.

According to the present invention, a magneto resistive element can reverse magnetization with less energy.

### BRIEF DESCRIPTION OF THE DRAWINGS

FIG. 1 is a cross-sectional view of a magneto resistive element according to a first embodiment.

FIG. 2 is a plan view of the magneto resistive element according to the first embodiment.

FIG. 3 is a cross-sectional view of the magneto resistive element according to a first modified example.

FIG. 4 is a cross-sectional view of a magneto resistive element according to a second modified example.

FIG. 5 is a cross-sectional view of a magneto resistive element according to a third modified example.

FIG. 6 is a cross-sectional view of a magnetic recording element according to a first application Example.

FIG. 7 is a cross-sectional view of a magnetic recording element according to a second application Example.

FIG. 8 is a cross-sectional view of a magnetic recording element according to a third application Example.

FIG. 9 is a cross-sectional view of a domain wall movement element according to a fourth application Example.

FIG. 10 is a cross-sectional view of a high-frequency device according to a fifth Application Example.

### DETAILED DESCRIPTION OF THE INVENTION

Hereinafter, the present embodiment will be described in detail with reference to the drawings as appropriate. In the drawings used in the following description, featured parts may be enlarged parts for convenience so that the features of the present invention are easier to understand, and dimensional ratios and the like of the respective components may be different from actual ones. Materials, dimensions, and the like exemplified in the following description are examples, the present invention is not limited thereto, and modifications can be appropriately made without departing from the subject matter of the present invention.

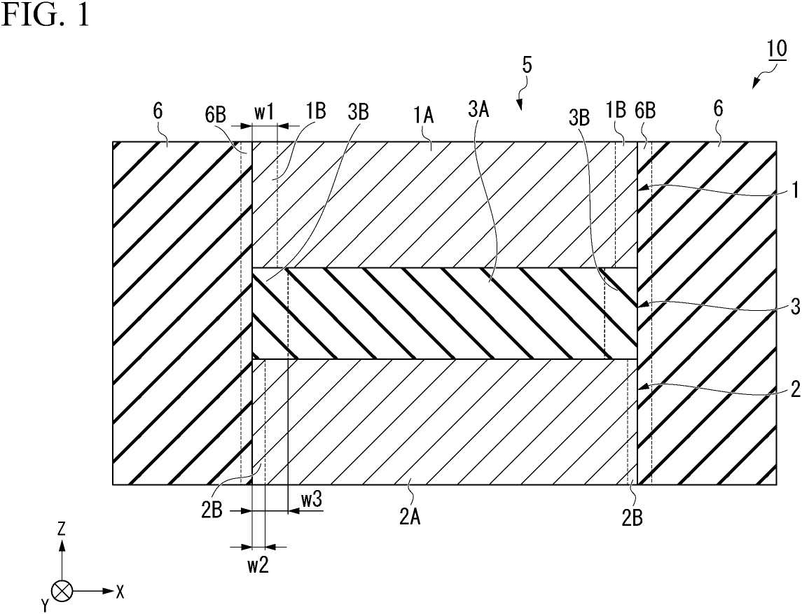

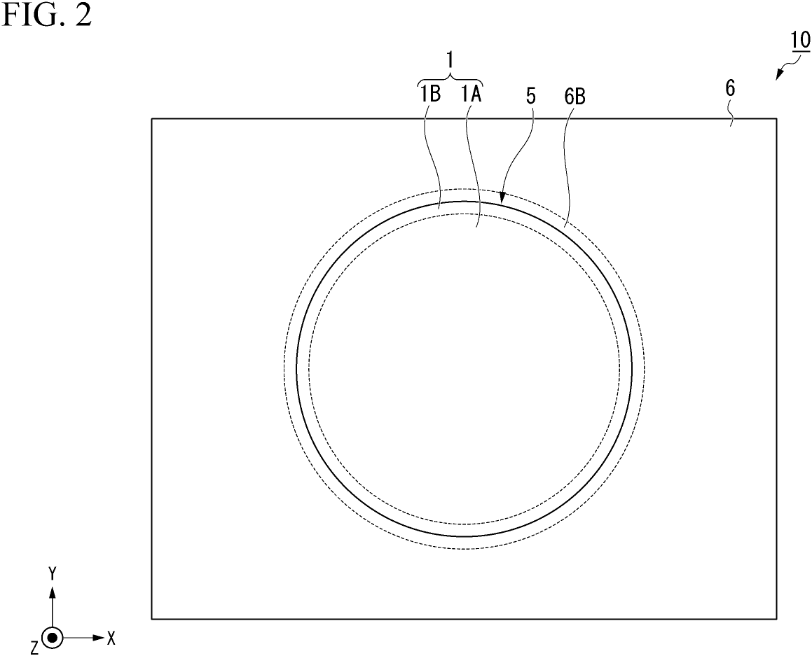

FIG. 1 is a cross-sectional view of a magneto resistive element 10 according to a first embodiment. FIG. 2 is a plan view of the magneto resistive element 10 according to the first embodiment.

Hereinafter, a lamination direction in which each layer is laminated is referred to as a Z-direction, a direction in which each layer spreads as one of the in-plane direction is referred to as an X-direction, and a direction orthogonal to the X-direction is referred to as a Y-direction.

The magneto resistive element 10 shown in FIG. 1 has a laminate 5 and an insulating layer 6. A plan-view shape of the laminate 5 is, for example, a circle. The plan-view shape of the laminate 5 is not limited to a circle and may be a rectangle, an ellipse, an oval, or the like. The insulating layer 6 covers at least a part of the side surface of the laminate 5. The insulating layer 6 surrounds, for example, the laminate 5.

The magneto resistive element 10 includes a first ferromagnetic layer 1, a second ferromagnetic layer 2, and a non-magnetic layer 3. The magneto resistive element 10 outputs a change in a resistance value caused by a change in a relative angle between the magnetization of the first ferromagnetic layer 1 and the magnetization of the second ferromagnetic layer 2.

The first ferromagnetic layer 1 contains a ferromagnet. The magnetization of the first ferromagnetic layer 1 rotates more easily than, for example, the magnetization of the second ferromagnetic layer 2. When a prescribed external force has been applied, a direction of magnetization of the second ferromagnetic layer 2 does not change (is fixed) and a direction of magnetization of the first ferromagnetic layer 1 changes. The first ferromagnetic layer 1 is a magnetization free layer.

The first ferromagnetic layer 1 has a first non-nitride region 1A and a first nitride region 1B. The first nitride region 1B is outside the first non-nitride region 1A. The first nitride region 1B is closer to the insulating layer 6 than the first non-nitride region 1A. The first nitride region 1B is, for example, an annular region surrounding the first non-nitride region 1A.

The first non-nitride region 1A is a region that does not contain nitrogen. The absence of nitrogen indicates that an amount of nitrogen detected in energy dispersive X-ray spectroscopy using a transmission electron microscope (TEM) is less than or equal to a detection limit. The first non-nitride region 1A is, for example, a ferromagnet having conductivity.

The first non-nitride region 1A includes, for example, a metal selected from the group consisting of Cr, Mn, Co, Fe, and Ni, an alloy containing one or more types of these metals, an alloy containing these metals and at least one or more elements of B, C, and N, and the like. The first non-nitride region 1A is, for example, a Co-Fe, Co-Fe-B, Ni-Fe, or Co-Ho alloy, a Sm-Fe alloy, a Fe-Pt alloy, a Co-Pt alloy, or a CoCrPt alloy.

The first non-nitride region 1A may be a Heusler alloy. The Heusler alloy includes an intermetallic compound with a chemical composition of XYZ or X₂YZ. X is a transition metal element or a noble metal element of the Co, Fe, Ni, or Cu groups on the periodic table, Y is a transition metal of the Mn, V, Cr, or Ti groups or an element of X, and Z is a typical element of Groups III to V. The Heusler alloy is, for example, Co₂FeSi, Co₂FeGe, Co₂FeGa, Co₂MnSi, Co₂Mn₁₋ₐFeₐAl_{b}Si_{1-b}, Co₂FeGe_{1-c}Ga_{c}, or the like. The Heusler alloy has a high spin polarization.

The first nitride region 1B is a ferromagnet containing nitrogen. The first nitride region 1B has conductivity. The first nitride region 1B which is nitrided has lower saturation magnetization than the first nitride region 1B which is not nitrided. That is, the magnetization of the first ferromagnetic layer 1 is easily inverted by nitridation.

The first nitride region 1B contains, for example, a material that is the same as that of the first non-nitride region 1A and the element nitrogen. The first nitride region 1B is, for example, a nitride or an oxynitride made of the same material as that of the first non-nitride region 1A. The first nitride region 1B has conductivity.

The first nitride region 1B is, for example, a nitride or an oxynitride containing one or more elements selected from the group consisting of Ni, Co, and Fe. The nitride of any one of Ni, Co, and Fe has a covalent bond. These nitrides prevent mutual diffusion of elements between the first ferromagnetic layer 1 and the insulating layer 6 and maintain the conductivity of the first ferromagnetic layer 1.

A width w1 of the first nitride region 1B is, for example, 3 nm or less. The first nitride region 1B is, for example, outside a position within a distance of 3 nm from an outside surface of the first ferromagnetic layer 1.

The second ferromagnetic layer 2 contains a ferromagnet. The magnetization of the second ferromagnetic layer 2 does not change in the direction of magnetization of the second ferromagnetic layer 2 when a prescribed external force is applied. The second ferromagnetic layer 2 is a magnetization fixed layer.

A coercive force difference between the first ferromagnetic layer 1 and the second ferromagnetic layer 2 can be controlled by, for example, the thicknesses of the first ferromagnetic layer 1 and the second ferromagnetic layer 2. For example, when the thickness of the first ferromagnetic layer 1 is made thinner than the thickness of the second ferromagnetic layer 2, the coercive force of the first ferromagnetic layer 1 becomes smaller than the coercive force of the second ferromagnetic layer 2.

Also, the coercive force may be increased by forming the second ferromagnetic layer 2 with a synthetic antiferromagnetic structure (a SAF structure). The synthetic antiferromagnetic structure includes two magnetic layers sandwiching the non-magnetic layer. For example, the second ferromagnetic layer 2 may be a laminate including a ferromagnetic layer, a spacer layer, and a ferromagnetic layer. Because the two ferromagnetic layers constituting the SAF structure are antiferromagnetically coupled, the coercive force of the second ferromagnetic layer 2 becomes larger than that in the case where there is no SAF structure. The magnetic layer constituting the SAF structure contains, for example, a ferromagnet, and may contain an antiferromagnet such as IrMn or PtMn. The spacer layer contains, for example, at least one selected from the group consisting of Ru, Ir, and Rh.

The second ferromagnetic layer 2 has a second non-nitride region 2A and a second nitride region 2B. The second nitride region 2B is outside the second non-nitride region 2A. The second nitride region 2B is closer to the insulating layer 6 than the second non-nitride region 2A. The second nitride region 2B is, for example, an annular region surrounding the second non-nitride region 2A.

The second non-nitride region 2A is a region that does not contain nitrogen. The second non-nitride region 2A is, for example, a ferromagnet having conductivity. A material similar to that of the first non-nitride region 1A can be used for the second non-nitride region 2A. The second non-nitride region 2A may have the same composition as the first non-nitride region 1A.

The second nitride region 2B is a ferromagnet containing nitrogen. The second nitride region 2B has conductivity. The second nitride region 2B which is nitrided has a smaller leakage magnetic field from the second nitride region 2B than the second nitride region 2B which is not nitride, reducing a magnetic field of an unnecessary bias applied to the first ferromagnetic layer 1.

The second nitride region 2B contains, for example, a material that is the same as that of the second non-nitride region 2A and the element nitrogen. The second nitride region 2B is, for example, a nitride or an oxynitride made of the same material as that of the second non-nitride region 2A. The second nitride region 2B has, for example, conductivity.

The second nitride region 2B is, for example, a nitride or an oxynitride containing one or more elements selected from the group consisting of Ni, Co, and Fe. The nitride of any one of Ni, Co, and Fe has a covalent bond. These nitrides prevent mutual diffusion of elements between the second ferromagnetic layer 2 and the insulating layer 6 and maintain the conductivity of the second ferromagnetic layer 2.

A width w2 of the second nitride region 2B is, for example, 3 nm or less. The second nitride region 2B is, for example, outside the position within a distance of 3 nm from an outside surface of the second ferromagnetic layer 2. The width w2 of the second nitride region 2B is narrower than, for example, a width w1 of the first nitride region 1B. If a nitride region is narrow, the saturation magnetization of the ferromagnetic layer is unlikely to decrease. When the above relationship is satisfied, it is possible to decrease a current density for magnetization reversal of the first ferromagnetic layer 1 that is a magnetization free layer while ensuring the magnetization stability of the second ferromagnetic layer 2 that is a magnetization fixed layer.

The non-magnetic layer 3 is sandwiched between the first ferromagnetic layer 1 and the second ferromagnetic layer 2. The non-magnetic layer 3 has a thickness in a range of, for example, 0.5 nm or more and 10 nm or less. The non-magnetic layer 3 inhibits the magnetic coupling between the first ferromagnetic layer 1 and the second ferromagnetic layer 2.

The non-magnetic layer 3 has a third non-nitride region 3A and a third nitride region 3B. The third nitride region 3B is outside the third non-nitride region 3A. The third nitride region 3B is closer to the insulating layer 6 than the third non-nitride region 3A. The third nitride region 3B is, for example, an annular region surrounding the third non-nitride region 3A.

The third non-nitride region 3A is a region that does not contain nitrogen. The third non-nitride region 3A is, for example, a non-magnetic material.

The third non-nitride region 3A may be a conductor, a semiconductor, or an insulator.

When the third non-nitride region 3A is a metal, its material is, for example, a metal or an alloy containing any element selected from the group consisting of Cu, Au, Ag, Al, and Cr. When the third non-nitride region 3A is a semiconductor, Si, Ge, CuInSe₂, CuGaSe₂, Cu(In, Ga)Se₂, or the like can be used as the material.

When the third non-nitride region 3A is an insulator, its material includes, for example, any one of MgO, Al₂O₃, and spinel-structured oxides represented by AB₂O₄. In the spinel-structured oxide represented by AB₂O₄, A is at least one of Mg and Zn, and B is at least one of Al, Ga, and In. The spinel-structured oxide represented by AB₂O₄ is, for example, MgAl₂O₄. When the non-magnetic layer 3 is an insulator, the non-magnetic layer 3 is called a tunnel barrier layer.

The third nitride region 3B is a non-magnetic material containing nitrogen. The third nitride region 3B which is nitrided prevents oxygen from diffusing into the insulating layer 6 when the third non-nitride region 3A is an oxide.

The third nitride region 3B contains, for example, a material that is the same as the third non-nitride region 3A and the element nitrogen. The third nitride region 3B is, for example, an oxynitride made of the same material as that of the third non-nitride region 3A.

A width w3 of the third nitride region 3B is, for example, wider than the width w1 of the first nitride region 1B and the width w2 of the second nitride region 2B. The first nitride region 1B has lower magnetic anisotropy than the first non-nitride region 1A and the second nitride region 2B has lower magnetic anisotropy than the second non-nitride region 2A. Thus, a spin polarization of the current passing through the first nitride region 1B and the second nitride region 2B is low. When the third nitride region 3B protrudes inward from the first nitride region 1B and the second nitride region 2B, the proportion of spin-polarized current with a low spin polarization applied to the first ferromagnetic layer 1 can be reduced.

The laminate 5 may have a layer other than the first ferromagnetic layer 1, the second ferromagnetic layer 2, and the non-magnetic layer 3 that have been described above. For example, a base layer may be provided below a lamination surface of the laminate 5 or a cap layer may be provided above the laminate 5. The base layer and the cap layer enhance the orientation of the crystals of the first ferromagnetic layer 1 and the second ferromagnetic layer 2. The base layer is, for example, a compound having a (001) oriented NaCl structure. The compound having a NaCl structure is, for example, a nitride containing at least one element selected from the group of Ti, Zr, Nb, V, Hf, Ta, Mo, W, B, Al, and Ce or an oxide containing at least one element selected from the group of Mg, Al, and Ce. The cap layer may include, for example, one or more metal elements of Ru, Ir, Ta, Ti, Al, Au, Ag, Pt, Cu, Cr, Mo, W, and Pd, an alloy of these metal elements, or a laminate of materials containing these metal elements of two or more types. Also, a buffer layer may be provided between the first ferromagnetic layer 1 and the non-magnetic layer 3 or between the second ferromagnetic layer 2 and the non-magnetic layer 3. The buffer layer is, for example, a NiAl layer. The buffer layer enhances the lattice matching of these interfaces.

The insulating layer 6 covers the periphery of the laminate 5. The insulating layer 6 is an insulating layer that insulates between the wirings of the multilayer wiring and between the elements. The insulating layer 6 is, for example, silicon oxide (SiOₓ), silicon nitride (SiNₓ), silicon carbide (SiC), chromium nitride (CrN), silicon carbide nitride (SiCN), silicon oxynitride (SiON), aluminum oxide (Al₂O₃), aluminum silicon oxide (AlSiO), zirconium oxide (ZrOₓ), magnesium oxide (MgO), aluminum nitride (AIN), tantalum oxide (TaO), titanium oxide (TiO), or the like.

The insulating layer 6 may have a nitride region 6B on a portion in contact with the laminate 5. The nitride region 6B is, for example, the above-mentioned nitride, oxynitride, or the like. The nitride region 6B has an insulating property.

Next, a method of manufacturing the magneto resistive element 10 will be described. First, a substrate serving as a base for film formation is prepared. The substrate may be crystalline or amorphous. Examples of the crystalline substrate include a metal oxide single crystal, a silicon single crystal, and a sapphire single crystal. Examples of the amorphous substrate include a silicon single crystal with a thermal oxide film, glass, ceramics, and quartz.

Next, the ferromagnetic layer serving as the second ferromagnetic layer 2, the non-magnetic layer serving as the non-magnetic layer 3, and the ferromagnetic layer serving as the first ferromagnetic layer 1 are sequentially laminated on the substrate. The layer serving as the second ferromagnetic layer 2 may be formed directly on the substrate or may be formed above the substrate via an insulating layer or the like. Each layer is formed in, for example, a sputtering method, a chemical vapor deposition method, a vapor deposition method, a laser ablation method, or a molecular beam epitaxy (MBE) method.

Next, a protection film is formed on a part of the upper portion of these laminated films. The laminated film is processed in a prescribed shape via the protection film. The processing can be performed in a method such as photolithography or ion milling. The laminated films become the laminate 5 according to processing and the side surface of the laminate 5 is exposed.

Next, nitrogen plasma treatment is performed. When the nitrogen plasma treatment is performed, the side surface of the laminate 5 is nitrided and the first nitride region 1B, the second nitride region 2B, and the third nitride region 3B are formed.

When the widths w1, w2, and w3 of the first nitride region 1B, the second nitride region 2B, and the third nitride region 3B are controlled, the laminated films are not processed all at once and the first ferromagnetic layer 1, the non-magnetic layer 3, and the second ferromagnetic layer 2 are sequentially processed. By performing nitrogen plasma treatment every time each layer is removed, the widths w1, w2, and w3 of the first nitride region 1B, the second nitride region 2B, and the third nitride region 3B can be controlled. For example, by performing the milling process while performing elemental analysis, for example, the processing can be stopped when only the ferromagnetic layer serving as the first ferromagnetic layer 1 is removed.

Although a method of forming a nitride region by performing the nitrogen plasma treatment has been described here, milling and nitriding may be performed at the same time by causing a gas for performing a milling process, for example, argon (Ar), krypton (Kr), or xenon (Xe), to contain nitrogen.

Next, the periphery of the laminate 5 is filled with the insulating layer 6. The insulating layer 6 is formed in, for example, a sputtering method, a chemical vapor deposition method, or a thin-film deposition method.

Next, the laminate 5 is annealed. The annealing temperature is, for example, 300° C. or lower, for example, 250° C. or higher and 300° C. or lower.

When the laminate is annealed, crystallization of the first ferromagnetic layer 1 and the second ferromagnetic layer 2 is performed. Also, a part of nitrogen in the first nitride region 1B, the second nitride region 2B, and the third nitride region 3B diffuses into the insulating layer 6 to form the nitride region 6B. According to such a procedure, the magneto resistive element 10 according to the first embodiment can be manufactured.

In the magneto resistive element 10 according to the present embodiment, the first ferromagnetic layer 1 has the first nitride region 1B, so that the saturation magnetization of the first ferromagnetic layer 1 can be lowered and an amount of energy required to reverse the magnetization of the first ferromagnetic layer 1 can be reduced. For example, the magneto resistive element 10 has a low current density for magnetization reversal required to reverse the magnetization of the first ferromagnetic layer 1.

Also, in the magneto resistive element 10 according to the present embodiment, the second ferromagnetic layer 2 has the second nitride region 2B, so that the unnecessary bias magnetic field applied to the first ferromagnetic layer 1 can be reduced.

Also, in the magneto resistive element 10 according to the present embodiment, the non-magnetic layer 3 has the third nitride region 3B, so that mutual diffusion of elements between the insulating layer 6 and the non-magnetic layer 3 can be prevented and an MR ratio of the magneto resistive element 10 can be increased.

Although the embodiments of the present invention have been described above in detail with reference to the drawings, the configurations and combinations thereof in the embodiments are examples and additions, omissions, substitutions, and other modifications of components can be made without departing from the spirit or scope of the present invention.

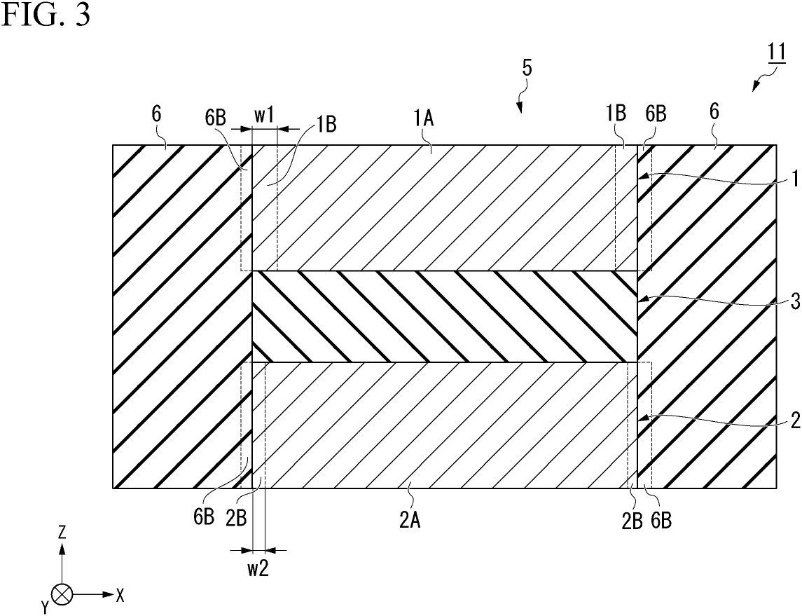

FIG. 3 is a cross-sectional view of the magneto resistive element 11 according to the first modified example. The magneto resistive element 11 is different from the magneto resistive element 10 in that the non-magnetic layer 3 does not have the third nitride region 3B. Components in the magneto resistive element 11 similar to those in the magneto resistive element 10 are denoted by similar reference signs and a description thereof will be omitted.

The non-magnetic layer 3 is similar to the above-described third non-nitride region 3A. The non-magnetic layer 3 contains, for example, any one of MgO, Al₂O₃, and spinel-structured oxides represented by AB₂O₄. In this case, the nitride region 6B of the insulating layer 6 is formed on a portion adjacent to the first ferromagnetic layer 1 and the second ferromagnetic layer 2.

The magneto resistive element 11 according to the first modified example has effects similar to those of the magneto resistive element 10 according to the first embodiment.

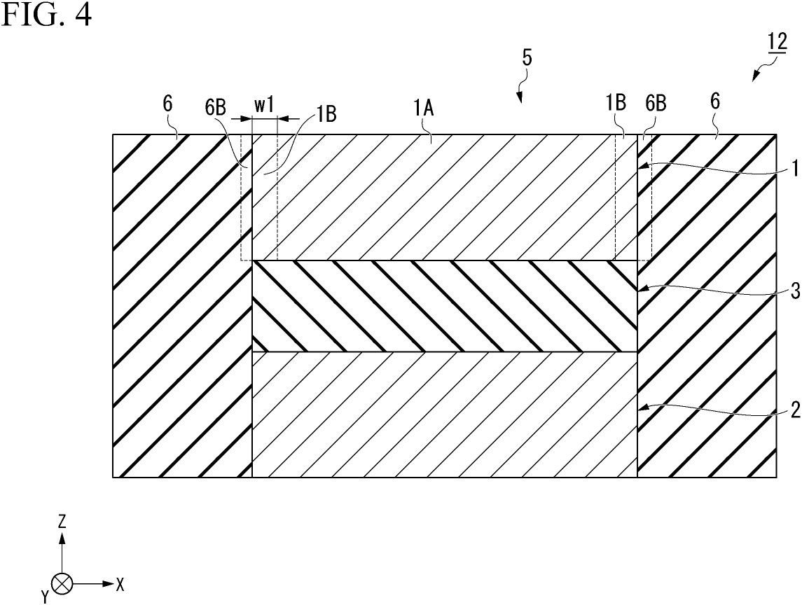

FIG. 4 is a cross-sectional view of the magneto resistive element 12 according to the second modified example. The magneto resistive element 12 is different from the magneto resistive element 10 in that the non-magnetic layer 3 does not have the third nitride region 3B and the second ferromagnetic layer 2 does not have the second nitride region 2B. Components in the magneto resistive element 12 similar to those in the magneto resistive element 10 are denoted by similar reference signs and a description thereof will be omitted.

The non-magnetic layer 3 is similar to the above-mentioned third non-nitride region 3A. The non-magnetic layer 3 contains, for example, any one of MgO, Al₂O₃, and spinel-structured oxides represented by AB₂O₄. The second ferromagnetic layer 2 is similar to the above-described second non-nitride region 2A. In this case, the nitride region 6B of the insulating layer 6 is formed on a portion adjacent to the first ferromagnetic layer 1.

The magneto resistive element 12 according to the second modified example has effects similar to those of the magneto resistive element 10 according to the first embodiment.

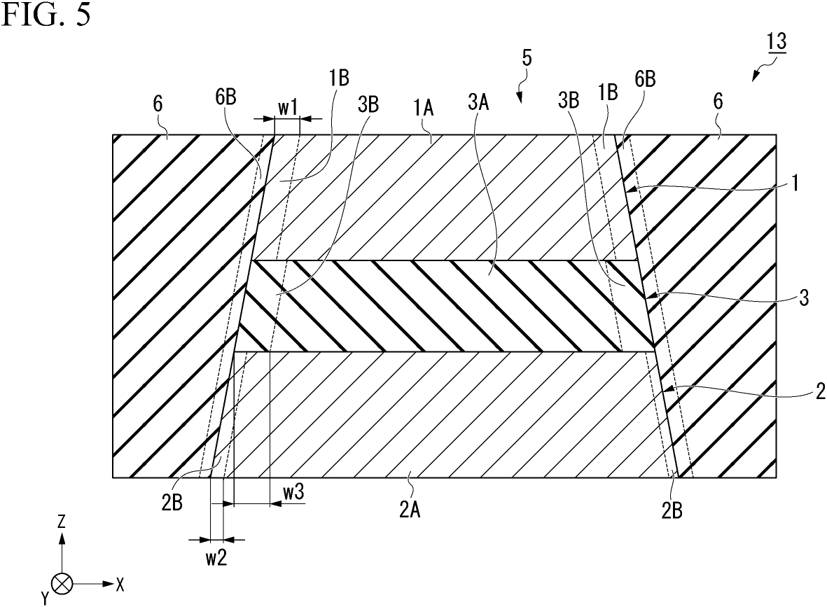

FIG. 5 is a cross-sectional view of the magneto resistive element 13 according to the third modified example. The magneto resistive element 13 has a cross-sectional shape of the laminate 5 different from that of the magneto resistive element 10. Components in the magneto resistive element 13 similar to those in the magneto resistive element 10 are denoted by similar reference signs and a description thereof will be omitted.

A circumferential length of the laminate 5 gradually increases from an upper surface to a lower surface. In an XZ cross-section, the side surface of the laminate 5 is inclined with respect to a Z-direction.

The magneto resistive element 13 according to the third modified example has effects similar to those of the magneto resistive element 10 according to the first embodiment.

The above-described magneto resistive element 10 can be used for various purposes. The magneto resistive element 10 can be applied to, for example, a magnetic head, a magnetic sensor, a magnetic memory, a high-frequency filter, and the like.

Next, an application example of the magneto resistive element according to the present embodiment will be described. Although the magneto resistive element 10 is used in the following application example, the magneto resistive element is not limited thereto.

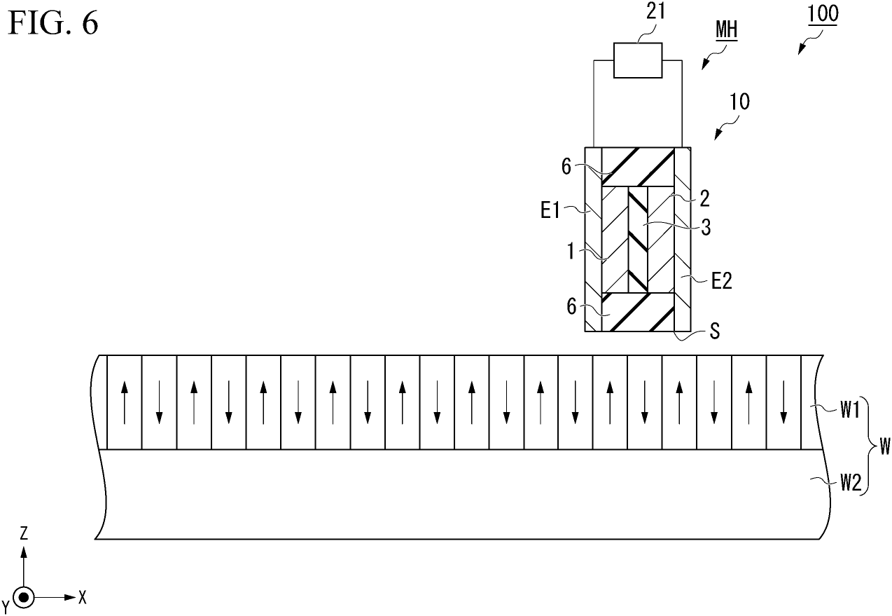

FIG. 6 is a cross-sectional view of the magnetic recording element 100 according to a first application example. FIG. 6 is a cross-sectional view of the magneto resistive element 10 cut along the lamination direction. FIG. 6 simultaneously illustrates electrodes E1 and E2 of the magneto resistive element 10.

As shown in FIG. 6, the magnetic recording element 100 has a magnetic head MH and a magnetic recording medium W. In FIG. 6, one direction in which the magnetic recording medium W extends is an X-direction and a direction perpendicular to the X-direction is a Y-direction. An XY plane is parallel to the main plane of the magnetic recording medium W. A direction in which the magnetic recording medium W and the magnetic head MH are connected and which is perpendicular to the XY plane is defined as a Z-direction.

In the magnetic head MH, an air bearing surface (medium facing surface) S faces the surface of the magnetic recording medium W. The magnetic head MH moves in directions of an arrow +X and an arrow -X along the surface of the magnetic recording medium W located at a certain distance away from the magnetic recording medium W. The magnetic head MH has a magneto resistive element 10 that acts as a magnetic sensor and a magnetic recording unit (not shown). The resistance measurement instrument 21 measures a resistance value of the magneto resistive element 10 in the lamination direction via the electrodes E1 and E2.

The magnetic recording unit applies a magnetic field to the recording layer W1 of the magnetic recording medium W and determines a direction of magnetization of the recording layer W1. That is, the magnetic recording unit performs a magnetic recording process for the magnetic recording medium W. The magneto resistive element 10 reads information of the magnetization of the recording layer W1 written by the magnetic recording unit.

The magnetic recording medium W has a recording layer W1 and a backing layer W2. The recording layer W1 is a portion for performing magnetic recording and the backing layer W2 is a magnetic path (a magnetic flux passage) along which a writing magnetic flux is recirculated to the magnetic head MH. The recording layer W1 records magnetic information as a direction of magnetization.

The first ferromagnetic layer 1 of the magneto resistive element 10 is, for example, a magnetization free layer. Thus, the first ferromagnetic layer 1 exposed on the air bearing surface S is affected by the magnetization recorded on the recording layer W1 of the opposing magnetic recording medium W. For example, in FIG. 6, the magnetization direction of the first ferromagnetic layer 1 is oriented in the +Z-direction due to the influence of the magnetization of the recording layer W1 in the +Z-direction. In this case, the magnetization directions of the first ferromagnetic layer 1 and the second ferromagnetic layer 2, which are the magnetization fixed layers, are parallel.

Here, the resistance when the magnetization directions of the first ferromagnetic layer 1 and the second ferromagnetic layer 2 are parallel is different from the resistance when the magnetization directions of the first ferromagnetic layer 1 and the second ferromagnetic layer 2 are antiparallel. As the difference between the resistance value when the layers are parallel and the resistance value when the layers are antiparallel increases, the MR ratio of the magneto resistive element 10 increases.

In the magneto resistive element 10 according to the present embodiment, the magnetization of the first ferromagnetic layer 1 is easily reversed. Therefore, the state of magnetization of the recording layer W1 can be sensitively read.

The shape of the magneto resistive element 10 of the magnetic head MH is not particularly limited. For example, the first ferromagnetic layer 1 may be installed at a position away from the magnetic recording medium W so that the influence of the leakage magnetic field of the magnetic recording medium W on the first ferromagnetic layer 1 of the magneto resistive element 10 is avoided.

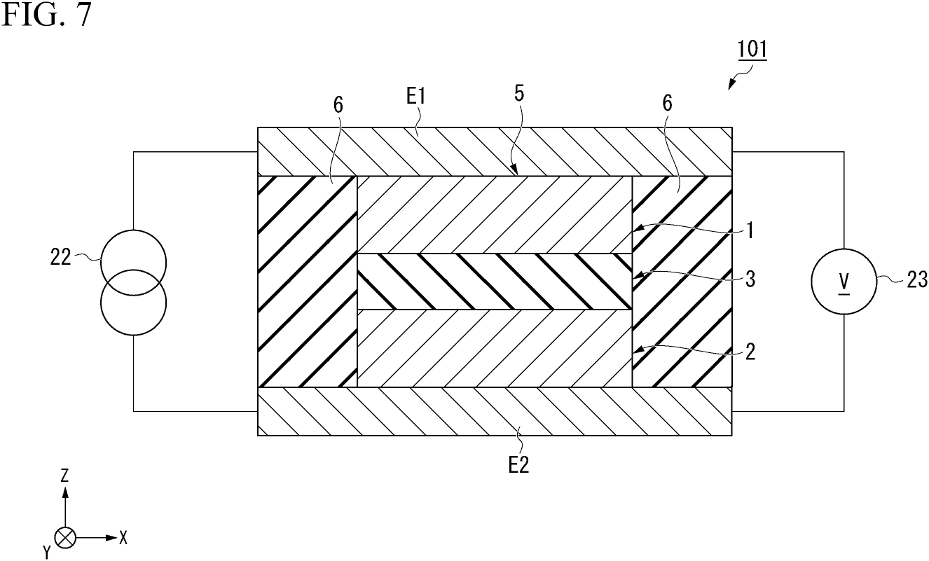

FIG. 7 is a cross-sectional view of the magnetic recording element 101 according to a second application example 2. FIG. 7 is a cross-sectional view of the magnetic recording element 101 cut along the lamination direction.

As shown in FIG. 7, the magnetic recording element 101 has a magneto resistive element 10, a power supply 22, and a measurement unit 23. The power supply 22 gives a potential difference in the lamination direction of the magneto resistive element 10. The power supply 22 is, for example, a direct current (DC) power supply. The measurement unit 23 measures the resistance value of the magneto resistive element 10 in the lamination direction.

When a potential difference is caused between the first ferromagnetic layer 1 and the second ferromagnetic layer 2 by the power supply 22, a current flows through the magneto resistive element 10 in the lamination direction. The current is spin-polarized when the current passes through the second ferromagnetic layer 2 and becomes a spin-polarized current. The spin-polarized current reaches the first ferromagnetic layer 1 via the non-magnetic layer 3. The magnetization of the first ferromagnetic layer 1 is affected by spin transfer torque (STT) due to the spin-polarized current and the magnetization is reversed. By changing the relative angle between the magnetization direction of the first ferromagnetic layer 1 and the magnetization direction of the second ferromagnetic layer 2, the resistance value of the magneto resistive element 10 in the lamination direction changes. The resistance value of the magneto resistive element 10 in the lamination direction is read by the measurement unit 23. That is, the magnetic recording element 101 shown in FIG. 7 is a spin transfer torque (STT) type magnetic recording element.

In the magnetic recording element 101 shown in FIG. 7, because the first ferromagnetic layer 1 easily performs the magnetization reversal, the current density for magnetization reversal can be lowered and the amount of energy required for writing data can be reduced.

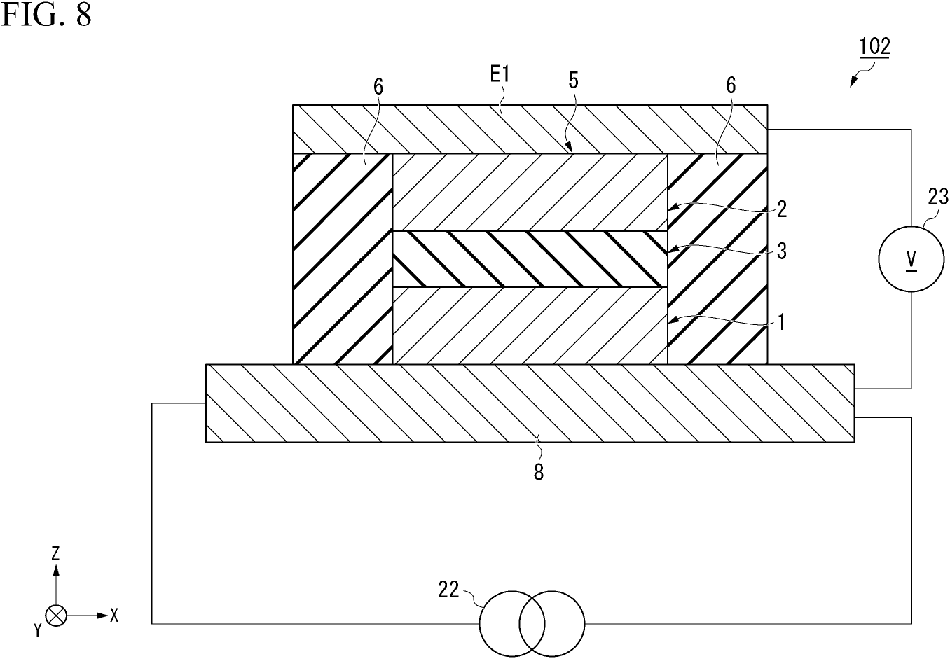

FIG. 8 is a cross-sectional view of the magnetic recording element 102 according to a third application example 3. FIG. 8 is a cross-sectional view of the magnetic recording element 102 cut along the lamination direction.

As shown in FIG. 8, the magnetic recording element 102 includes a magneto resistive element 10, a spin-orbit torque wiring 8, a power supply 22, and a measurement unit 23. The spin-orbit torque wiring 8 is in contact with, for example, the first ferromagnetic layer 1. The spin-orbit torque wiring 8 extends in one of in-plane directions. The power supply 22 is connected to a first end and a second end of the spin-orbit torque wiring 8. The magneto resistive element 10 is sandwiched between the first end and the second end in a plan view. The power supply 22 causes a write current to flow along the spin-orbit torque wiring 8. The measurement unit 23 measures the resistance value of the magneto resistive element 10 in the lamination direction.

When a potential difference is created between the first end and the second end of the spin-orbit torque wiring 8 by the power supply 22, a current flows through the spin-orbit torque wiring 8 in the in-plane direction. The spin-orbit torque wiring 8 has a function of generating a spin current according to the spin Hall effect when a current flows. The spin-orbit torque wiring 8 contains, for example, any one of a metal, an alloy, an intermetal compound, a metal boride compound, a metal carbide, a metal silicate, and a metal phosphate having a function of generating a spin flow according to the spin Hall effect when a current flows. For example, the wiring includes a non-magnetic metal having an atomic number of 39 or more having d-electrons or f-electrons in the outermost shell.

When a current flows through the spin-orbit torque wiring 8 in the in-plane direction, the spin Hall effect is generated according to the spin-orbit interaction. The spin Hall effect is a phenomenon in which a moving spin is bent in a direction orthogonal to the current flow direction. The spin Hall effect creates the uneven distribution of spins in the spin-orbit torque wiring 8 and induces a spin current in the thickness direction of the spin-orbit torque wiring 8. The spin is injected from the spin-orbit torque wiring 8 into the first ferromagnetic layer 1 by the spin current.

The spin injected into the first ferromagnetic layer 1 gives spin-orbit torque (SOT) to the magnetization of the first ferromagnetic layer 1. The first ferromagnetic layer 1 receives the spin-orbit torque (SOT) and makes magnetization reversal. By changing a relative angle between the magnetization direction of the first ferromagnetic layer 1 and the magnetization direction of the second ferromagnetic layer 2, the resistance value of the magneto resistive element 10 in the lamination direction changes. The resistance value of the magneto resistive element 10 in the lamination direction is read by the measurement unit 23. That is, the magnetic recording element 102 shown in FIG. 8 is a spin-orbit torque (SOT) type magnetic recording element.

In the magnetic recording element 102 shown in FIG. 8, because the magnetization of the first ferromagnetic layer 1 is easily reversed, the current density for magnetization reversal can be lowered and the amount of energy required for writing data can be reduced.

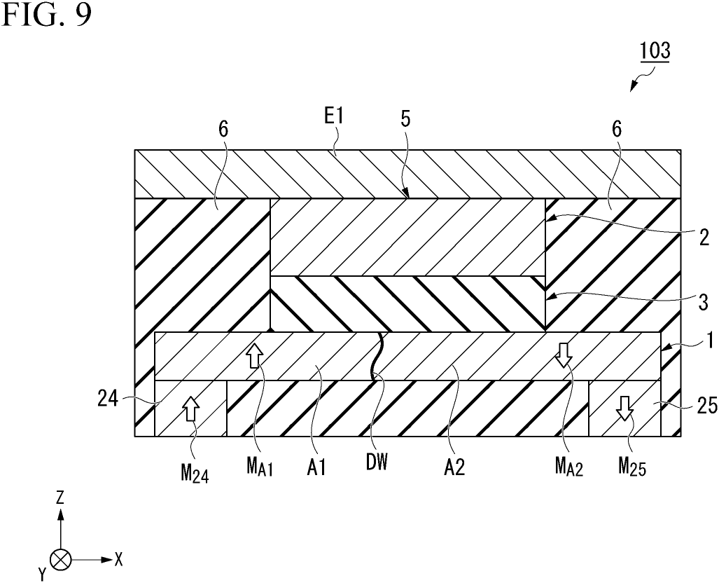

FIG. 9 is a cross-sectional view of a domain wall movement element (a domain wall movement type magnetic recording element) according to a fourth application example 4. The domain wall movement element 103 has a magneto resistive element 10, a first magnetization fixed layer 24, and a second magnetization fixed layer 25. The magneto resistive element 10 includes a first ferromagnetic layer 1, a second ferromagnetic layer 2, and a non-magnetic layer 3. In FIG. 9, a direction in which the first ferromagnetic layer 1 extends is an X-direction, a direction perpendicular to the X direction is a Y-direction, and a direction perpendicular to the XY plane is a Z-direction.

The first magnetization fixed layer 24 and the second magnetization fixed layer 25 are connected to a first end and a second end of the first ferromagnetic layer 1. The first end and the second end sandwich the second ferromagnetic layer 2 and the non-magnetic layer 3 in the X-direction.

The first ferromagnetic layer 1 is a layer capable of magnetically recording information due to a change in an internal magnetic state. The first ferromagnetic layer 1 has a first magnetic domain A1 and a second magnetic domain A2 inside. The magnetization at a position overlapping the first magnetization fixed layer 24 or the second magnetization fixed layer 25 within the first ferromagnetic layer 1 in the Z-direction is fixed in one direction. The magnetization at the position overlapping the first magnetization fixed layer 24 in the Z-direction is fixed in, for example, the +Z-direction, and the magnetization at the position overlapping the second magnetization fixed layer 25 in the Z-direction is fixed in, for example, the -Z-direction. As a result, a domain wall DW is formed at a boundary between the first magnetic domain A1 and the second magnetic domain A2. The first ferromagnetic layer 1 can have the domain wall DW inside. In the first ferromagnetic layer 1 shown in FIG. 9, magnetization M_{A1} of the first magnetic domain A1 is oriented in the +Z-direction and magnetization M_{A2} of the second magnetic domain A2 is oriented in the -Z-direction.

The domain wall movement element 103 can record data in multiple values or continuously according to the position of the domain wall DW of the first ferromagnetic layer 1. The data recorded on the first ferromagnetic layer 1 is read as a change in the resistance value of the domain wall movement element 103 when a read current is applied.

A ratio of the first magnetic domain A1 and the second magnetic domain A2 in the first ferromagnetic layer 1 changes as the domain wall DW moves. For example, the magnetization of the second ferromagnetic layer 2 is in the same direction (parallel) as the magnetization M_{A1} of the first magnetic domain A1 and is in the direction opposite (antiparallel) to the magnetization M_{A2} of the second magnetic domain A2. When the domain wall DW moves in the +X-direction and the area of the first magnetic domain A1 in the portion overlapping the second ferromagnetic layer 2 in a plan view from the Z-direction becomes large, the resistance value of the domain wall movement element 103 becomes small. In contrast, when the domain wall DW moves in the -X-direction and an area of the second magnetic domain A2 in the portion overlapping the second ferromagnetic layer 2 in the plan view from the Z-direction becomes large, the resistance value of the domain wall movement element 103 becomes large.

The domain wall DW moves by causing a write current to flow through the first ferromagnetic layer 1 in the X direction or by applying an external magnetic field. For example, when a write current (for example, a current pulse) is applied to the first ferromagnetic layer 1 in the +X-direction, electrons flow in the -X-direction opposite to the direction of the current, so that the domain wall DW moves in the -X-direction. When a current flows from the first magnetic domain A1 to the second magnetic domain A2, the electrons spin-polarized in the second magnetic domain A2 cause the magnetization M_{A1} of the first magnetic domain A1 to be reversed. The domain wall DW moves in the -X-direction by reversing the magnetization M_{A1} of the first magnetic domain A1.

In the domain wall movement element 103 shown in FIG. 9, because the magnetization of the first ferromagnetic layer 1 is easily reversed, the current density for magnetization reversal can be lowered and the amount of energy required for writing data can be reduced.

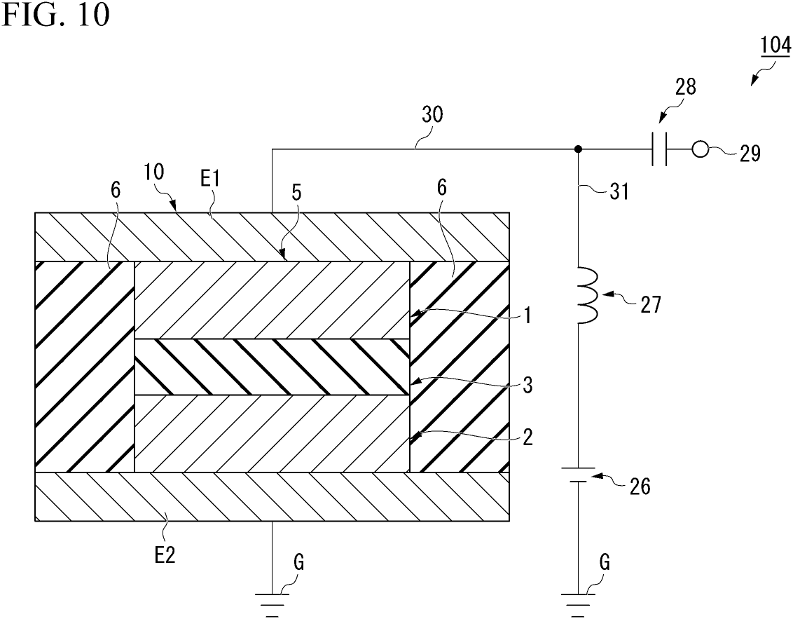

FIG. 10 is a schematic diagram of the high-frequency device 104 according to a fifth application Example. As shown in FIG. 10, the high-frequency device 104 has a magneto resistive element 10, a DC power supply 26, an inductor 27, a capacitor 28, an output port 29, and wirings 30 and 31.

The wiring 30 connects the magneto resistive element 10 and the output port 29. The wiring 31 branches from the wiring 30 and reaches the ground G via the inductor 27 and the DC power supply 26. The DC power supply 26, the inductor 27, and the capacitor 28, which are known, can be used. The inductor 27 cuts the high-frequency component of the current and allows the invariant component of the current to pass through. The capacitor 28 allows a high-frequency component of the current to pass through and cuts an invariant component of the current. The inductor 27 is arranged on a portion where the flow of a high-frequency current is desired to be limited and the capacitor 28 is arranged on a portion where the flow of a DC is desired to be limited.

When an alternating current (AC) or an AC magnetic field is applied to the ferromagnetic layer contained in the magneto resistive element 10, the magnetization of the first ferromagnetic layer 1 undergoes an aging motion. The magnetization of the first ferromagnetic layer 1 vibrates strongly when the frequency of the high-frequency current or the high-frequency magnetic field applied to the first ferromagnetic layer 1 is close to the ferromagnetic resonance frequency of the first ferromagnetic layer 1 and does not vibrate particularly when the frequency of the high-frequency current or the high-frequency magnetic field applied to the first ferromagnetic layer 1 is away from the ferromagnetic resonance frequency of the first ferromagnetic layer 1. This phenomenon is called a ferromagnetic resonance phenomenon.

The resistance value of the magneto resistive element 10 changes due to the vibration of the magnetization of the first ferromagnetic layer 1. The DC power supply 26 applies a DC to the magneto resistive element 10. The DC flows through the magneto resistive element 10 in the lamination direction. The DC flows to the ground G through the wirings 30 and 31 and the magneto resistive element 10. The potential of the magneto resistive element 10 changes according to Ohm’s law. A high-frequency signal is output from the output port 29 in response to a change in a potential of the magneto resistive element 10 (a change in a resistance value).

In the high-frequency device 104 shown in FIG. 10, because the first ferromagnetic layer 1 easily performs magnetization reversal, a current density for magnetization reversal can be lowered and a high-frequency signal can be transmitted with high efficiency.

### EXPLANATION OF REFERENCES

1 First ferromagnetic layer
1A First non-nitride region
1B First nitride region
2 Second ferromagnetic layer
2A Second non-nitride region
2B Second nitride region
3 Non-magnetic layer
3A Third non-nitride region
3B Third nitride region
5 Laminate
6 Insulating layer
6B Nitride region
8 Spin-orbit torque wiring
10, 11, 12 Magneto resistive element
21 Resistance measurement instrument
22 Power supply
23 Measurement unit
24 First magnetization fixed layer
25 Second magnetization fixed layer
26 DC power supply
27 Inductor
28 Capacitor
29 Output port
30, 31 Wiring
100, 101, 102 Magnetic recording element
103 Domain wall movement element
104 High-frequency device
DW Domain wall
A1 First magnetic domain
A2 Second magnetic domain

What is claimed is:

1. A magneto resistive element comprising:
a laminate including a first ferromagnetic layer, a second ferromagnetic layer, and a non-magnetic layer; and
an insulating layer configured to cover at least a part of a side surface of the laminate,
wherein the non-magnetic layer is located between the first ferromagnetic layer and the second ferromagnetic layer, and
wherein the first ferromagnetic layer has a first non-nitride region and a first nitride region that is closer to the insulating layer than the first non-nitride region and contains nitrogen.

2. The magneto resistive element according to claim 1, wherein the second ferromagnetic layer has a second non-nitride region and a second nitride region that is closer to the insulating layer than the second non-nitride region and contains nitrogen.

3. The magneto resistive element according to claim 1, wherein the first nitride region is a nitride or an oxynitride containing one or more elements selected from the group consisting of Ni, Co, and Fe.

4. The magneto resistive element according to claim 2, wherein the second nitride region is a nitride or an oxynitride containing one or more elements selected from the group consisting of Ni, Co, and Fe.

5. The magneto resistive element according to claim 1,
wherein the non-magnetic layer contains any one of MgO, Al₂O3, and spinel-structured oxides represented by AB₂O₄, and
wherein, in the spinel-structured oxide represented by AB₂O₄, A is at least one of Mg and Zn and B is at least one of Al, Ga, and In.

6. The magneto resistive element according to claim 1, wherein the non-magnetic layer has a third non-nitride region and a third nitride region that is closer to the insulating layer than the third non-nitride region and contains nitrogen.

7. The magneto resistive element according to claim 6, wherein the third nitride region is an oxynitride containing an element constituting the non-magnetic layer.

8. The magneto resistive element according to claim 1, wherein the insulating layer contains a nitride in a portion in contact with the laminate.

9. The magneto resistive element according to claim 1, wherein a width of the first nitride region is 3 nm or less.

10. The magneto resistive element according to claim 2, wherein a width of the second nitride region is 3 nm or less.

11. The magneto resistive element according to claim 1,
wherein the second ferromagnetic layer has a second non-nitride region and a second nitride region that is closer to the insulating layer than the second non-nitride region and contains nitrogen, and
wherein a width of the second nitride region is narrower than a width of the first nitride region.

12. The magneto resistive element according to claim 1,
wherein the second ferromagnetic layer has a second non-nitride region and a second nitride region that is closer to the insulating layer than the second non-nitride region and contains nitrogen,
wherein the non-magnetic layer has a third non-nitride region and a third nitride region that is closer to the insulating layer than the third non-nitride region and contains nitrogen, and
wherein a width of each of the first nitride region and the second nitride region is narrower than a width of the third nitride region.
